(19) United States
(12) Patent Application Publication
(10) Pub. No.: US 2023/0417682 A1
(43) Pub. Date: Dec. 28, 2023

(54) METROLOGY SOLUTIONS FOR COMPLEX STRUCTURES OF INTEREST

(71) Applicant: Onto Innovation Inc., Wilmington, MA (US)

(72) Inventors: Jingsheng SHI, Singapore (SG); Pei Fen TEH, Singapore (SG); Jie LI, San Jose, CA (US); Youxian WEN, Fremont, CA (US); Wei Ming CHIEW, Singapore (SG)

(73) Assignee: Onto Innovation Inc., Wilmington, MA (US)

(21) Appl. No.: 18/339,971

(22) Filed: Jun. 22, 2023

Related U.S. Application Data
(60) Provisional application No. 63/355,053, filed on Jun. 23, 2022.
(60) Provisional application No. 63/498,475, filed on Apr. 26, 2023.

(51) Int. Cl. G01N 21/95; G06N 20/00

(52) U.S. Cl. CPC G01N 21/9501; G06N 20/00

(57) ABSTRACT

Complex structures, such as gate-all-around (GAA) field effect transistor or high-aspect ratio (HAR) Channel hole etch, etc., in semiconductor devices are measured using a combination of physical modeling and machine learning modeling. Metrology signals collected at different manufacturing process steps, e.g., pre-process step and post-process step of the structure of interest (SOI) may be used. The measurement signals acquired at the pre-process steps are used to determine a first parameter of the SOT, e.g., using physical modeling and machine learning, which may be fed forward and used to generate a physical model of the SOI at the post-process step. A second parameter of the SOI at the post-process step is determined using physical modeling and machine learning and may be fed back and used to generate the physical model of the SOI at the post-process step with post process signals and used to determine other parameters.

### CROSS REFERENCE TO RELATED APPLICATIONS

This application claims priority under 35 U.S.C. § 119 to U.S. Provisional Application No. 63/355,053, filed Jun. 23, 2022, entitled “METROLOGY SOLUTIONS FOR GATE-ALL-AROUND TRANSISTORS,” and U.S. Provisional Application No. 63/498,475, filed Apr. 26, 2023, entitled “MULTIPLE SOURCES OF SIGNALS FOR HYBRID METROLOGY USING PHYSICAL MODELING AND MACHINE LEARNING,” both of which are assigned to the assignee hereof and are incorporated herein by reference in their entireties.

### FIELD OF THE DISCLOSURE

The subject matter described herein are related generally to metrology, and more particularly to modeling and measuring structures using multiple data sources and a combination of physical modeling and machine learning.

### BACKGROUND

Semiconductor and other similar industries often use metrology, such as optical metrology or X-ray metrology, to provide non-contact evaluation of samples during processing. With optical metrology, for example, a sample under test is illuminated with light, e.g., at a single wavelength or multiple wavelengths. After the light interacts with the sample, the resulting light is detected and analyzed to determine one or more characteristics of the sample.

The analysis typically includes modeling the structure under test. The model may be generated based on the physical properties of the structure, such as the materials and the nominal parameters of the structure, e.g., film thicknesses, optical properties of material, line and space widths, etc., and is therefore sometimes referred to as a physical model. One or more parameters of the model may be varied and the predicted data may be calculated for each parameter variation based on the model, e.g., using Rigorous Coupled Wave Analysis (RCWA) or other similar techniques. The measured data may be compared to the predicted data for each parameter variation, e.g., in a nonlinear regression process, until a good fit is achieved between the predicted data and the measured data, at which time the fitted parameters are considered an accurate representation of the parameters of the structure under test. Modeling, however, may be time consuming and computationally intensive, and expensive, particularly for small complex features.

### SUMMARY

Complex structures, such as gate-all-around (GAA) field effect transistor or high-aspect ratio (HAR) Channel hole etch, etc., in semiconductor devices are measured using a combination of physical modeling and machine learning modeling. Additionally, metrology signals are collected at different manufacturing process steps, e.g., at a pre-process step and at a post-process step for the structure of interest (SOI). The measurement signals acquired at the pre-process step are used to determine a first parameter of the SOI, e.g., using physical modeling and machine learning, which may be fed forward and used to generate a physical model of the SOI at the post-process step to improve accuracy. A second parameter of the SOI at the post-process step is determined using physical modeling and machine learning and may be fed back and used to generate the physical model of the SOI at the post-process step to improve sensitivity and break the parameter correlation.

In one implementation, a method for measuring multiple parameters of interest from a structure of interest (SOI) includes obtaining post-process step measured signals from a metrology device for a SOI on one or more samples at a post-process step. The method further includes extracting post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof. The method further includes predicting a final value of the second parameter for the SOI at the post-process step from a trained post-process machine learning model based on the post-process measurement results extracted from the post-process physical model and providing at least the final value of the second parameter for the SOI.

In one implementation, a computer system configured for measuring multiple parameters of interest from a structure of interest (SOI) includes at least one processor, where the at least one processor is configured to obtain post-process step measured signals from a metrology device for a SOI on one or more samples at a post-process step. The at least one processor is further configured to extract post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof. The at least one processor is further configured to predict a final value of the second parameter for the SOI at the post-process step from a trained post-process machine learning model based on the post-process measurement results extracted from the post-process physical model and provide at least the final value of the second parameter for the SOI.

In one implementation, a system for measuring multiple parameters of interest from a structure of interest (SOI) includes means for obtaining post-process step measured signals from a metrology device for a SOI on one or more samples at a post-process step. The system further includes means for extracting post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof. The system further includes means for predicting a final value of the second parameter for the SOI at the post-process step from a trained post-process machine learning model based on the post-process measurement results extracted from the post-process physical model and means for providing at least the final value of the second parameter for the SOI.

### BRIEF DESCRIPTION OF THE DRAWINGS

FIG. 1A illustrates examples of planar transistor architecture, fin transistor architecture, and gate-all-around (GAA) field effect transistor architectures.

FIG. 1B illustrates an example of a GAA transistor.

FIG. 2 illustrates a schematic view of a metrology device that may be used to characterize a sample as discussed herein.

FIG. 3 illustrates a workflow for offline recipe creation in accordance with a first example scenario with signals collected from multiple data sources, including different tools and/or sources.

FIG. 4 illustrates a workflow for inline measurement in accordance with the first example scenario with signals collected from multiple data sources, including different tools and/or sources.

FIG. 5 illustrates a workflow for offline recipe creation in accordance with a second example scenario with signals collected from multiple data sources, including different manufacturing process steps.

FIG. 6 illustrates a workflow for inline measurement in accordance with the second example scenario with signals collected from multiple data sources, including different manufacturing process steps.

FIG. 7 illustrates a workflow for offline recipe creation in accordance with a third example scenario with signals collected from multiple data sources, e.g., different manufacturing process steps.

FIG. 8 illustrates a workflow for inline measurement in accordance with the third example scenario with signals collected from multiple data sources, including different manufacturing process steps.

FIGS. 9-10 illustrates flowcharts depicting methods for characterizing a device on a sample based on multiple data sources.

### DETAILED DESCRIPTION

During fabrication of semiconductor and similar devices it is often necessary to monitor the fabrication process by non-destructively measuring the devices. One type of metrology that may be used for non-destructive measurement of samples during processing is optical metrology, which may use a single wavelength or multiple wavelengths, and may include, e.g., ellipsometry, reflectometry, Fourier Transform infrared spectroscopy (FTIR), etc. Other types of metrology may also be used, including X-ray metrology, opto-acoustic metrology, electron beam (E-beam) metrology, etc.

Optical metrology, such as thin film metrology and Optical Critical Dimension (OCD) metrology, and other types of metrology, sometimes use physical modeling techniques to generate predicted data of a sample that is compared with the measured data from the sample. With physical modeling techniques, a model of the sample is generated that includes key and non-key parameters. The model may be based on nominal parameters of the sample and may include one or more variable parameters, such as layer thicknesses, line widths, space widths, sidewall angles, material properties, etc., that may be varied over a desired range, e.g., depending on the process parameters used to fabricate the sample under test. The model may further include parameters related to the tool set, e.g., characteristics of the optical system used by the metrology device. Predicted data may be calculated based on the parameters of the physical model, including variations of the variable parameters, and characteristics of the metrology device using analytical or semi-analytical methods, such as effective medium theory (EMT), finite-difference time-domain (FDTD), transfer matrix method (TMM), the Fourier modal method (FMM)/rigorous coupled-wave analysis (RCWA), the finite element method (FEM), etc. Measured data acquired from the sample by the metrology device is compared to the predicted data for different parameter variations, e.g., in a nonlinear regression process, until a best fit is achieved, at which time the values of the fitted parameters are considered to be an accurate representation of the parameters of the sample.

Conventionally, modeling requires that preliminary structural and material information of the sample to be known in order to generate an accurate representative model of the sample, including one or more variable parameters. For example, the preliminary structural and material information for a sample may include the type of structure and a physical description of the sample with nominal values for various parameters, such as layer thicknesses, line widths, space widths, sidewall angles, material properties, etc., along with a range within which these parameters may vary. The model may further include one or parameters that are not variable, i.e., are not expected to change in the sample by a significant amount during manufacturing. The variable parameters of the model are adjusted and the predicted data may be produced in real time during the non-linear regression process, or a library may be pre-generated. Thus, modeling applies physical constraints in the analysis and accordingly offers a high level of fidelity for the measurement results. However, modeling has a high computation cost due to the physical calculations necessary to generate the predicted data. For example, modeling complex 3D structures suffers from a slow time to solution (TTS) and modeling accuracy may be degraded due to difficulties in fitting data for complex structures.

Another technique that may be used to generate predicted data for a sample based on measured data acquired from a sample by a metrology device is machine learning. Machine learning algorithms that may be used for metrology, for example, may include, but are not limited to, linear regression, neural networks, deep learning, convolution neural-network (CNN), ensemble methods, support vector machine (SVM), random forest, etc., or combination of multiple models in sequential mode and/or parallel mode. Machine learning does not require a physical model of the sample. Instead, reference data, e.g., measured data acquired from one or more reference samples by the metrology device, is obtained, along with the values of structure parameters of interest, and is used to generate and train a machine learning model. The machine learning models are automatically trained using the reference data and the known values of the structure parameters to find relevant data features and learn the intrinsic relationship and connections between input and output features in order to make decisions and predictions for new data. The benefit of the use of machine learning is a fast time to solution (TTS) and minimal requirements for computing resources. However, machine learning requires a large amount of reference data which is costly and time-consuming to obtain. Without a large amount of reference data, the machine learning model may suffer from overfitting due to the lack of physical constraints.

As semiconductor devices continue to shrink, metrology budgets become tighter. Additionally, complex 3D structures are being adopted more frequently to enable continued device scaling. Semiconductor technology advancements, such as the use of complex 3D structures, place additional challenges on metrology due to increased modeling complexities and parameter correlation, and reduced sensitivity. Signals from a single metrology tool or source, for example, may not have sufficient sensitivities to measure parameters of interest accurately for semiconductor process quality control. Ultimately, there may be no single metrology tool that can handle all metrology requirements for most advanced semiconductor devices.

As discussed herein, with the use of data collected from multiple data sources, e.g., from multiple tool sets and/or process steps and the use of additional data related to the samples that is collected from metrology and/or production equipment, such as sensor data, a computationally efficient data analysis method may fuse the multiple data sources and produce more accurate and consistent measurement results than what can be provided by any individual data source. The analysis method may be flexible to accommodate a variety of data of different nature, while at the same time maximize usage of existing well-developed techniques, such as physical modeling or machine learning, for each type of data source and synergize the strength of individual metrology technology.

As discussed herein, physical modeling and machine learning are combined to analyze multiple sources of data for hybrid metrology and ecosystem. The method described herein creates predictive power through data mining and data fusion from multiple data sources, e.g., multiple metrology tool sets, sample data from multiple process steps, metrology equipment parameters, and production equipment parameters. By way of example, physical models may be used to analyze metrology signals from one or more metrology tools, such as spectroscopic ellipsometer, spectroscopic reflectometer, X-ray metrology, opto-acoustic metrology, Fourier Transform infrared spectroscopy (FTIR), E-beam metrology, etc., to extract measurement results for key and non-key parameters of a sample at a pre-process step and at a post-process step. Additionally, machine learning models may be built and trained to predict parameters of interest for the sample at a pre-process step and at a post-process step. A post-process physical model that extracts post-process measurement signals may use predicted parameters of interest from the pre-process step predicted by a pre-process physical model or a pre-process machine learning model by feedforward. Additionally or alternatively, predicted parameters of interest from the post-process step can be fed back to the post-process physical model or post-process machine learning model to determine other parameters of interest.

The proposed techniques can be used to combine and analyze multiple sources of data in an efficient and flexible way of synergizing physical modeling and machine learning with controllable computation cost and software and modeling complexities, thus provides most viable solutions with manageable time to solution (TTS) and improved final results and overall metrology performance. The approach is also universal and can be applied to measurements of any devices, OCD, thin film, or other types of targets.

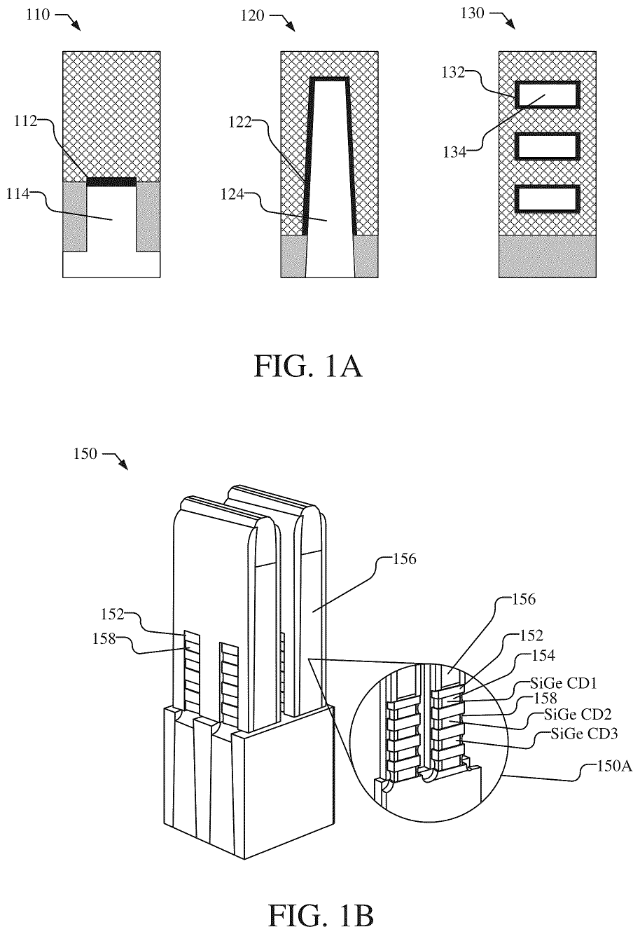

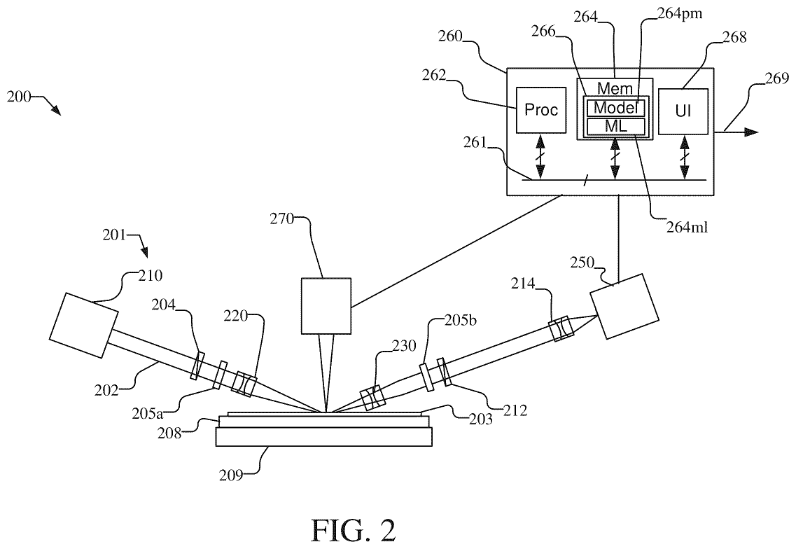

FIG. 1A, by way of example, illustrates semiconductor devices 110, 120, and 130 with planar, fin, and gate-all-around (GAA) field effect transistor architectures, respectively. A planar transistor architecture used in device 110 uses a gate 112 positioned over a channel 114 to control the flow of current through the channel between a source and a drain. A voltage applied to the gate creates an electric field (FET—field effect transistor) that excludes or permits carriers in the channel thus turning the current on or off. The source, channel, and drain are coplanar, created at the surface of a semiconductor wafer, with the gate positioned over the channel. To combat effects such as increasing leakage currents, that degraded their performance due to decreased size, finFETs were adopted, as illustrated in device 120, in which the channel 124 has the shape of a fin, surrounded on three sides by the gate 122. The use of gate 122 increases the effective area of the gate 122 in proximity to the channel 124. Limitations have been encountered for finFETs, however, and other, more complex, architectures have been adopted. For example, device 130 uses a gate-all-around (GAA) design in which the gate 132 completely surrounds the channel 134. The GAA transistor device 130 includes multiple vertically stacked nanosheet channels 134 passing through a single gate 132. While GAA devices 130 promise continuing improvement in performance, the three dimensional features and small size greatly increase the complexity of the manufacturing process and require accurate monitoring using non-destructive metrology.

FIG. 1B, for example, illustrates a more detailed view of a GAA transistor device 150 during fabrication, including a cross-sectional view 150A that runs lengthwise through the silicon (Si) channels 152 between a source and drain (not shown). The GAA transistor device 150 is illustrated showing the Si channels 152 that will be completely surrounded by the gate when silicon germanium (SiGe) layers 154 and a dummy gate 156 are replaced. FIG. 1B illustrates three repeating SiGe regions with different critical dimensions (CDs), e.g., SiGe CD1, SiGe CD2, and SiGe CD3.

The GAA fabrication process flow bears similarity to finFET processes, e.g., used to produce device 120 shown in FIG. 1A. The process begins, for example, with the creation of a superlattice, a stack of alternating, epitaxially deposited silicon and silicon germanium (SiGe) layers. Trenches are etched through the lattice to create fin-like structures, with each fin containing three to four silicon nanosheet layers that will become the transistor Si channels 152 separated by the SiGe layers 154. The silicon layers alternate with SiGe layers that will be replaced by gate materials. Dummy polysilicon gates 156 are deposited across the nanosheet-fins and spacer material conformally deposited over the dummy gates. Source and drain are etched on either side of the gate, cutting through and exposing the ends of the Si channels 152. In a series of important steps, the exposed SiGe layers between the ends of the Si channels 152 are selectively etched to create cavities for the inner spacers 158, and inner spacers are then deposited in the cavities. These features are extremely small and yet their dimensions are considered critical in determining the performance of the device for several reasons. For example, the depth of the cavity and inner spacer determines the length of the gate, the inner spacer protects the subsequently deposited source and drain during layer release when the dummy gate is etched away and replaced with gate materials, and the spacer suppresses parasitic capacitance between the source/drain and gate.

Accordingly, accurate monitoring these components in a GAA transistor device, or other, similar, components in GAA transistor devices or other complex 3D structures, is important during manufacturing, but is difficult using conventional metrology techniques.

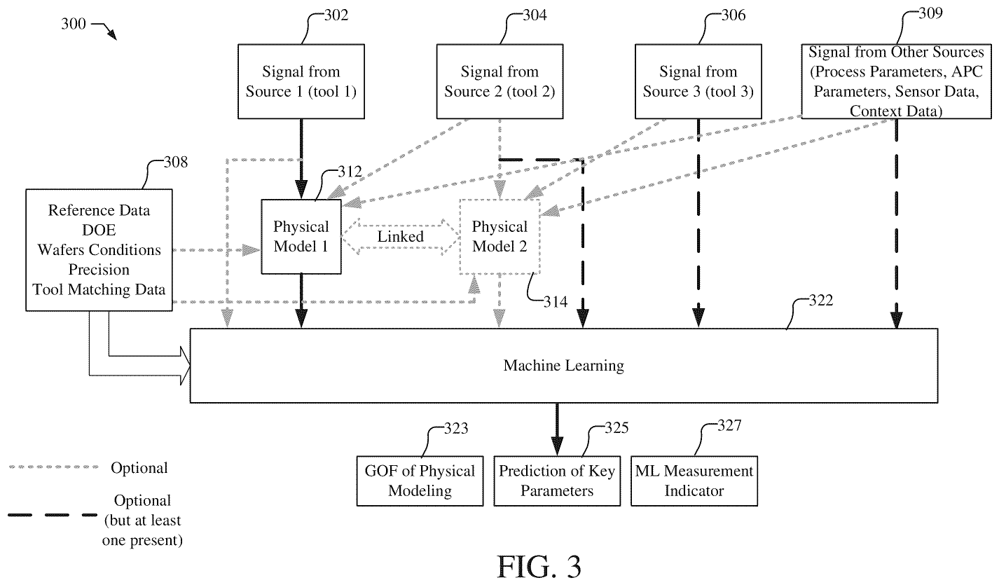

FIG. 2, by way of example, illustrates a schematic view of a metrology device 200 that may be used to characterize a structure on a sample, as described herein. The metrology device 200 may be configured to perform one or more types of measurements, such as, e.g., spectroscopic reflectometry, spectroscopic ellipsometry (including Mueller matrix ellipsometry), spectroscopic scatterometry, overlay scatterometry, interferometry, opto-acoustic metrology, E-beam metrology, X-ray metrology, FTIR measurements, etc. of a sample 203. Metrology device 200, for example, may include a first metrology tool 201 and a second metrology tool 270, but may include additional metrology tools, or may be coupled to receive sample data measured by a separate metrology tool. It should be understood that metrology device 200 is illustrated as one example configuration for a metrology device, and that if desired other configurations and other metrology devices may be used.

Metrology device 200 includes an oblique incidence metrology tool 201 that includes a light source 210 that produces light 202. The light 202, for example, may be UV-visible light with wavelengths, e.g., between 200 nm and 1000 nm. The light 202 produced by light source 210 may include a range of wavelengths, i.e., continuous range or a plurality of discrete wavelengths, or may be a single wavelength. The metrology device 200 includes focusing optics 220 and 230 that focus and receive the light and direct the light to be obliquely incident on a top surface of the sample 203. The optics 220, 230 may be refractive, reflective, or a combination thereof and may be an objective lens.

The reflected light may be focused by lens 214 and received by a detector 250. The detector 250, may be a conventional charge coupled device (CCD), photodiode array, CMOS, or similar type of detector. The detector 250 may be, e.g., a spectrometer if broadband light is used, and detector 250, for example, may generate a spectral signal as a function of wavelength. A spectrometer may be used to disperse the full spectrum of the received light into spectral components across an array of detector pixels. One or more polarizing elements may be in the beam path of the metrology device 200. For example, metrology device 200 may include one or both (or none) of one or more polarizing elements 204 in the beam path before the sample 203, and a polarizing element (analyzer) 212 in the beam path after the sample 203, and may include one or more additional elements 205a and 205b, such as a compensator or photoelastic modulator, which may be before, after, or both before and after the sample 203. With the use of a spectroscopic ellipsometer using dual rotating compensators, between polarizing elements 204 and 212 and the sample, a full Mueller matrix may be measured.

Metrology device 200 may include or may be coupled to additional metrology devices. For example, as illustrated, metrology device 200 may include a second, normal incidence, metrology tool 270. The second metrology tool 270, by way of example, may be configured for spectroscopic reflectometry, spectroscopic scatterometry, overlay scatterometry, interferometry, E-beam metrology, X-ray metrology, FTIR measurements, etc. In some implementations, the metrology device 200 may include additional tools, e.g., a third (or more) metrology tools. In some implementations, additional metrology tools may be separate from the metrology device 200.

Metrology device 200 further includes one or more computing systems 260 that is configured to characterize one or more parameters of the sample 203 using the methods described herein. The one or more computing systems 260 is coupled to the first metrology tool 201, e.g., detector 250, and the second metrology tool 270 and any additional metrology tools, if present, to receive the metrology data acquired during measurement of the structure of the sample 203. The acquisition of data may be performed during a pre-process fabrication step as well as a post-process fabrication step. The one or more computing systems 260, for example, may be a workstation, a personal computer, central processing unit or other adequate computer system, or multiple systems.

It should be understood that the one or more computing systems 260 may be a single computer system or multiple separate or linked computer systems, which may be interchangeably referred to herein as computing system 260, at least one computing system 260, one or more computing systems 260. The computing system 260 may be included in or is connected to or otherwise associated with metrology device 200, and any additional metrology tools. Different subsystems of the metrology device 200 may each include a computing system that is configured for carrying out steps associated with the associated subsystem. The computing system 260, for example, may control the positioning of the sample 203, e.g., by controlling movement of a stage 209 that is coupled to the chuck. The stage 209, for example, may be capable of horizontal motion in either Cartesian (i.e., X and Y) coordinates, or Polar (i.e., R and θ) coordinates or some combination of the two. The stage may also be capable of vertical motion along the Z coordinate. The computing system 260 may further control the operation of the chuck 208 to hold or release the sample 203. The computing system 260 may further control or monitor the rotation of one or more polarizing elements 204, 212, or additional elements 205a, 205b, etc.

The computing system 260 may be communicatively coupled to the detector 250 in the first metrology tool 201 and to a detector in the second metrology tool 270 (if present) in any manner known in the art. For example, the one or more computing systems 260 may be coupled to a separate computing system that is associated with the detector 250. The computing system 260 may be configured to receive and/or acquire metrology data, e.g., from the detector 250, as well as controllers polarizing elements 204, 212, and additional elements 205a, 205b, etc., as well as components of the second metrology tool 270, via a transmission medium that may include wireline and/or wireless portions. The transmission medium, thus, may serve as a data link between the computing system 260 and other subsystems of the metrology device 200. The computing system 260 may be further configured to receive and/or acquire additional information about the sample and one or more subsystems of the first metrology tool 201 and production equipment, e.g., from a user interface (UI) 268 or via a transmission medium that may include wireline and/or wireless portions.

The computing system 260, which includes at least one processor 262 with memory 264, as well as the UI 268, which are communicatively coupled via a bus 261. The memory 264 or other non-transitory computer-usable storage medium, includes computer-readable program code 266 embodied thereof and may be used by the computing system 260 for causing the at least one computing system 260 to control the metrology device 200 and to perform the functions including the techniques and analysis described herein. For example, as illustrated, memory 264 may include instructions for causing the processor 262 to perform both modeling and machine learning, and in some implementations, may employ feedforward and/or feedback, as discussed herein. The data structures and software code for automatically implementing one or more acts described in this detailed description can be implemented by one of ordinary skill in the art in light of the present disclosure and stored, e.g., on a computer-usable storage medium, e.g., memory 264, which may be any device or medium that can store code and/or data for use by a computer system, such as the computing system 260. The computer-usable storage medium may be, but is not limited to, include read-only memory, a random access memory, magnetic and optical storage devices such as disk drives, magnetic tape, etc. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described.

The computing system 260, for example, may be configured to obtain data for reference samples that may include a structure-of-interest, such as a 3D complex structure including but not limited to a GAA transistor, from multiple data sources, including from one or both metrology tools 201 and 270, and any desired additional metrology tools, as well as data related to the sample, such as reference data and/or design of experiment (DOE) data, and data related to the metrology tools and/processing equipment, such as process parameters, Advanced Parameter Control (APC) parameters, context data, and sensor data from production equipment. DOE data, for example, may be measured data from a set of reference samples processed with intentionally introduced skew conditions so that the structure parameters of interest are varied by the skewed process conditions with known patterns. The computing system 260 may be configured to generate and use one or more physical models (Model 264pm) for the sample, based on measured data from one or more reference samples and optionally additional information related to the sample and/or processing equipment, and generate, train, and use one or more machine learning models (ML 264ml) for the sample, based on measurement results extracted from the one or more physical models and data, as discussed herein. In some implementations, a different computing system and/or different metrology device(s) may be used to acquire the metrology data and additional information from training samples and generate one or more physical models (Model 264pm) and/or generate and train one or more machine learning models (ML 264ml), and the resulting physical models and/or trained machine learning models (or portions thereof) may be provided to the computing system 260, e.g., via the computer-readable program code 266 on non-transitory computer-usable storage medium, such as memory 264.

The computing system 260 may be additionally or alternatively used to acquire data from a test sample from multiple data sources. The data may be the same type used to generate the physical model(s) and to generate and train the machine learning model(s) discussed above, and the test sample has the same structure, e.g., with the SOI, as the reference samples. The computing system 260 may be configured to determine one or more parameters of interest for the SOI using the data from multiple sources and the one or more physical models (Model 264pm) and the one or more trained machine learning models (ML 264ml), as discussed herein.

The results from the analysis of the data may be reported, e.g., stored in memory 264 associated with the sample 203 and/or indicated to a user via UI 268, an alarm or other output device. Moreover, the results from the analysis may be reported and fed forward or fed back to the process equipment to adjust the appropriate fabrication steps to compensate for any detected variances in the fabrication process. The computing system 260, for example, may include a communication port 269 that may be any type of communication connection, such as to the internet or any other computer network. The communication port 269 may be used to receive instructions that are used to program the computing system 260 to perform any one or more of the functions described herein and/or to export signals, e.g., with measurement results and/or instructions, to another system, such as external process tools, in a feedforward or feedback process in order to adjust a process parameter associated with a fabrication process step of the samples based on the measurement results.

As discussed herein, for characterizing a SOI, e.g., complex 3D structures including but not limited to GAA transistors, to be measured, (1) at least one physical based model is built to analyze metrology signals from one tool or multiple tools such as spectroscopic ellipsometry (SE), spectroscopic reflectometry (SR), X-ray, E-beam, opto-acoustic data, Fourier-transform infrared spectroscopy (FTIR) etc., and from one or more sources to extract measurement results for key and non-key parameters. Additionally, (2) at least one machine learning model is built and trained to predict parameters of interest. The machine learning model may take one of more of the following data as inputs: a) the measurement results (key and non-key parameters) from the physical model(s) from (1); b) the raw signal for physical model(s) from (1) and optionally the misfit; data sources from different tool sets, or the same tool in (1) but not included in physical modeling; process parameters, APC parameters, context data; and sensor data from production equipment. Additionally, (3) in line measurement of the SOI may be performed using the physical model(s) and machine learning model(s) created and trained offline to make predictions the parameters of interest based on data from multiple data sources.

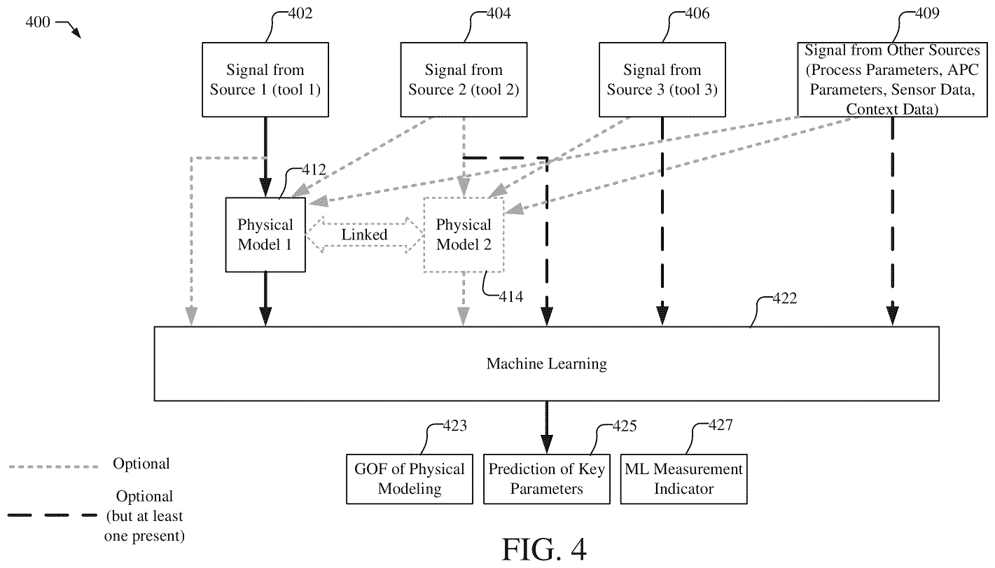

FIG. 3, by way of example, illustrates a workflow 300 for offline recipe creation, e.g., generating one or more physical models and one or more machine learning models, in accordance with a first example scenario with data collected from multiple data sources, e.g., different tools and/or sources. In FIG. 3, solid black arrows indicate processes that are used in the workflow 300, dashed black arrows indicate processes that are optional, but at least one is present, while dotted grey arrows indicate processes that are optional.

As illustrated, measured signals 302 from one or more reference samples are collected from a first data source or tool (Source 1). The measured signals 302 from a SOI may be collected from any desired metrology device, such as metrology tool 201 shown in FIG. 2, or from any other desired type of metrology device.

Additionally, data is acquired from one or more additional data sources. For example, in some implementations, measured signals 304 and 306 from the one or more reference samples may be collected from one or more additional sources or tools, e.g., illustrated as a second source or tool (Source 2) and a third source or tool (Source 3). The additional measured signals 304, for example, may be collected from metrology device that is different than Source 1, such as metrology tool 270 shown in FIG. 2, or from any other desired type of metrology device, and the measured signals 306 may be collected from a metrology device that is different than Source 1 and Source 2, such as a different type of measurement from either of metrology tools 201 or 270 or from any other desired type of metrology device. Additional data 308 related to the SOI may be collected and used as training data for one or more machine learning models 322, as illustrated with the block arrow. The additional data 308, for example may include reference data for the sample and the DOE data. Reference data, for example, may be measured data acquired from one or more reference sample by the metrology device along with the values of structure parameters of interest typically provided by CD-AFM (atomic force microscopy), CD-SEM (scanning electron microscopy) or TEM (Transmission electron microscopy). Reference data and/or DOE data may be used as training data set to train machine learning models to find relevant data features and learn the intrinsic relationship and connections between input and output features in order to make decisions and predictions for new data. In some implementations, the additional data 308 related to the reference samples may further include wafer conditions, precision, tool matching data, etc. Precision data, for example, are a parameter based on repeatedly measured data from the same target at multiple times from same instance of tool. Precision is another metrology key performance indicator (KPI) that indicates the consistency of measured results from multiple runs for the same sample. Tool matching data, for example, are a parameter based on measured data from the same sample from multiple instances of tool of same tool type. Tool matching is another metrology KPI that indicates the consistency of measured results from different tools of same type for the same sample. Measurement accuracy (evaluated by matching to reference values provided from CD-AFM, CD-SEM, TEM etc. and/or consistence to DOE conditions), precision and tool matching are typical metrology KPIs. If precision and tool matching data are provided, physical modeling or machine learning models may be optimized to not only to closely match reference values, but also to predict consistent results for a same sample with measured signals from multiple runs from the same tool or from different tools of same type.

Further, in some implementations, additional data signals 309 may be used as inputs for physical models or input features for machine learning models. The additional data signals 309, for example, may be related to the sources (e.g., Source 1, Source 2, and Source 3) may be obtained, such as process parameters, Advanced Process Control (APC) parameters, context data; and sensor data from production equipment. By way of example, some process control parameters, e.g., substrate temperature and chemical concentration for wet etch can impact etch rate (how fast materials are removed from surface of the wafer), and etch rate is one of the important factors to determine etch depth and CD profile. Some of these parameters, such as temperature, are measured by sensors from production equipment. Other parameters, such as etch time, name of etch chambers, are user-controlled parameters. Name of the etch chambers is an example of context data. Since each etch chamber has its own characteristic distribution of etch profiles across wafer, knowing this information may help machine learning predict a correct wafer map. An example of APC parameters is atomic force microscope (AFM) results measured from the same sample at different process steps that contain relevant information, e.g., non-key parameters for the structure of interests. Adding the non-key parameters as machine learning input features can help improve machine learning robustness on predicting key parameters. Adding all these relevant parameters as machine learning input features may provide additional information that helps determine structure parameters of interest controlled by these process parameters and conditions.

The measured signals and data from the multiple data sources may be used to generate one or more physical models of the SOI. For example, as illustrated with the solid black arrow, the measured signals 302 from the first source (Source 1) may be used to generate a first physical model 312 of the sample. A physical model of a sample, for example, is created based on known geometry, nominal values, and materials of the structure. The measured signals 302 may be used to generate the first physical model 312 by providing data from which measurement results are extracted, and the first physical model 312 may be adjusted and optimized so that the calculated signals are a good fit to the measured signals and a good match between the extracted measurement results and the known parameters of the reference samples is achieved. In some implementations, additional data may be used to assist in generating the first physical model 312. For example, as illustrated with the dotted grey arrow, additional data 308, such as the reference data and/or DOE, and optionally the wafer conditions, precision, and tool matching data, may also be used to assist in the generation of the first physical model 312. Additionally, as illustrated with the grey dotted arrow, the data signals 309 may be used to assist in the generation of the first physical model 312. In another example, as illustrated with the dotted grey arrow, the measured signals 304 from the second source (Source 2) may be used to assist in the generation of the first physical model 312 of the sample. In some implementations, both additional data 308 and measured signals 304 may be used to assist in the generation of the first physical model 312.

In some implementations, multiple physical models may be generated. For example, as illustrated with the grey dotted arrows and grey dotted box, a second physical model 314 may be generated based on measured signals 304 from the second source (Source 2). In some implementations, additional data may be used to generate the second physical model 314. For example, as illustrated by the dotted grey arrow, additional data 308, such as the reference data and/or DOE, and optionally the wafer conditions, precision, and tool matching data, may also be used to assist in the generation of the second physical model 314. In another example, as illustrated with the dotted grey arrow, the measured signals 306 from the third source (Source 3) may be used to assist in the generation of the second physical model 314 of the sample. In some implementations, both additional data 308 and measured signals 306 may be used to assist in the generation of the second physical model 314. Additionally, as illustrated with the grey dotted arrow, the data signals 309 may be used to assist in the generation of the second physical model 314. Moreover, the multiple physical models may be optimized independently or co-optimized. For example, in some implementations, as illustrated with dotted grey lines, the first physical model 312 and the second physical model 314 may be linked so that at least some parameters may be coupled across the physical models 312 and 314 and the combined parameter space may be searched to fit the measured signals from one or multiple data sources. The first physical model 312, and optionally, the second physical model 314, may be configured to provide goodness of fit 323 of the physical modeling.

One or more machine learning models 322 is built and trained using the multiple data sources to predict parameters of interest 325. A machine learning measurement indicator 327 can be developed and reported together with the goodness of fit from the physical modeling to indicate the measurement quality of the recipe synergized from physical modeling and machine learning. As illustrated with the solid black arrows, the machine learning model 322 is built using the measurement results extracted by the first physical model 312 as input features. As indicated with the dashed black arrows, the input features of the machine learning model 322 may additionally include at least one of measured signals 304 from the one or more reference samples collected from the second source (Source 2), measured signals 306 from the one or more reference samples collected from the third source (Source 3), additional data signals 309, the measurement results extracted by the second physical model 314, or any combination thereof. In some implementations, as illustrated with the dotted grey arrow, the input features of the machine learning model 322 optionally may include the measured signals 302 from the one or more reference samples collected from the first source (Source 1). In some implementations, the input features from the measured signals 302 may include a data channel or a data chunk that are not used in generating the first physical model 312. For example, in general, a data channel may be a measurement subsystem that is defined by at least one of the energy source, such as the light source, the optical path directed by optical parts, the detector, or any combination thereof, and a data chunk may be a subset of wavelengths (e.g., as used in spectroscopic metrology), frequencies (e.g., as used in frequency resolved metrology), angles (e.g., as used in angular resolved metrology), time span (e.g., as used in time resolved metrology), or any combination of the above from a full data set provided by a data channel. For example, the first metrology device may collect normal incidence signals and oblique incidence spectroscopic ellipsometer (SE) signals. The SE signals may be used to generate the first physical model 312, but the normal incidence signals may not be used, as it may be difficult to fit the normal incidence signals. The normal incidence signals, thus, may be a data channel that is used as data for machine learning model 322 input features, in addition to the physical modeling results produced from a different data channel, e.g., the SE signals. In another example, the same data channel may be split into multiple data chunks, e.g., signals from different wavelength ranges, and some data chunks may be difficult to fit using physical modeling, but may be used as data for the machine learning model 322 input features.

The machine learning model 322 is trained with at least a portion of the data 308, such as the reference data and/or DOE, and optionally the wafer conditions, precision, and tool matching data. The data 308 is training data and used for offline training. For example, reference data may be a set of signals (e.g., including any of the measurement results from the first physical model 312, measured signals 304, measured signals 306, additional data signals 309, and measured signals 302) with labels (e.g., values of key parameter provided by other metrology systems such as CD-SEM, TEM, CD-AFM). During training of the machine learning model 322, the set of signals from the reference data are used as machine learning input features, and based on these input features, the machine learning model 322 makes predictions for the key parameters. The machine learning model 322 is trained to learn and make predictions for key parameters that match the labels of the reference data. The DOE from data 308 are a set of signals (e.g., including any of the measurement results from the first physical model 312, measured signals 304, measured signals 306, additional data signals 309, and measured signals 302) measured from reference samples processed with intentionally introduced skew conditions. During machine learning training, the machine learning model 322 takes the signals from DOE data as input features and make predictions for key parameters. The machine learning model 322 is trained so that the predicted key parameter values follow the expected skew pattern based on the process skew conditions. Precision data from data 308 are measured signals (e.g., including any of the measurement results from the first physical model 312, measured signals 304, measured signals 306, additional data signals 309, and measured signals 302) from the same sample but on multiple runs from same metrology tool. Similarly, tool matching data from data 308 are signals (e.g., including any of the measurement results from the first physical model 312, measured signals 304, measured signals 306, additional data signals 309, and measured signals 302) from the same sample but measured from different instances of metrology tools of same type. The machine learning model 322 takes precision and tool matching data as input features and makes predictions. The machine learning model 322 is trained so that the predicted values for key parameters are consistent for the signals measured from the same samples but from different runs or different tools. The machine learning model 322 can be trained so that all the criteria, matching to reference values, DOE skew conditions, high precision and consistent tool matching are met at the same time if all these data are provided during training.

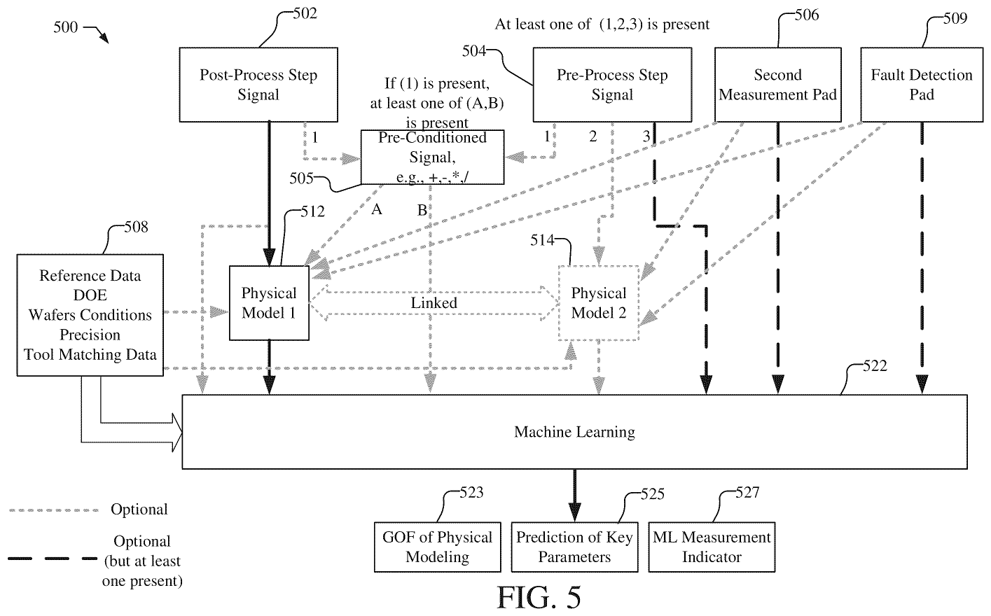

FIG. 4, by way of example, illustrates a workflow 400 for inline measurement, e.g., for characterizing a sample based on one or more physical models and one or more machine learning models, in accordance with the first example scenario with signals collected from multiple data sources, e.g., different tools and/or sources. The one or more physical models and one or more machine learning models, for example, may be generated as discussed in reference to FIG. 4. In FIG. 4, solid black arrows indicate processes that are used in the workflow 400, dashed black arrows indicate processes that are optional, but at least one is present, while dotted grey arrows indicate processes that are optional.

As illustrated, measured signals 402 from the SOI from the sample are collected from a first data source or tool (Source 1). The measured signals 402 may be collected from any desired metrology device, such as metrology tool 201 shown in FIG. 2, or from any other desired type of metrology device, and may be collected from the same metrology device or same type of metrology device as used for Source 1 in FIG. 3.

Additionally, data is acquired from one or more additional data sources. For example, in some implementations, measured signals 404 and 406 may be collected from one or more additional sources or tools, e.g., illustrated as a second source or tool (Source 2) and a third source or tool (Source 3). The additional measured signals 404, for example, may be collected from metrology device that is different than Source 1, such as metrology tool 270 shown in FIG. 2, or from any other desired type of metrology device, and may be collected from the same metrology device or same type of metrology device as used for Source 2 in FIG. 3. The measured signals 406 may be collected from a metrology device that is different than Source 1 and Source 2, such as a different type of measurement from either of metrology tools 201 or 270 or from any other desired type of metrology device and may be collected from the same metrology device or same type of metrology device as used for Source 3 in FIG. 3. Further, in some implementations, additional data signals 409, for example, that may be related to the sources (e.g., Source 1, Source 2, and Source 3), may be obtained, such as process parameters, APC parameters, context data; and sensor data from production equipment.

The signals and data from the multiple data sources may be used to extract measurement results from one or more physical models. For example, as illustrated with the solid black arrows, the measured signals 402 from the first source (Source 1) may be used to extract measurement results for the SOI of the sample from a first physical model 412, which may be the same as the first physical model 312 in FIG. 3. In some implementations, additional data may be used to assist in extracting measurement results from the first physical model 412. For example, as illustrated with the dotted grey arrow, the measured signals 404 from the second source (Source 2) may be used to assist in the extraction of measurement results from the first physical model 412 of the sample.

Additionally, as illustrated with the dotted grey arrow, additional data signals 409 may be used to assist in extracting measurement results for the sample from the first physical model 412.

In some implementations, multiple physical models may be used to extract measurement results for the sample. For example, as illustrated with the grey dotted arrows and grey dotted box, a second physical model 414 may be used to extract measurement results for the sample based on measured signals 404 from the second source (Source 2). The second physical model 414, for example, may be the same as the second physical model 314 in FIG. 3. In some implementations, additional data may be used to assist in extracting measurement results from the second physical model 414. For example, as illustrated with the dotted grey arrow, the measured signals 406 from the third source (Source 3) may be used to assist in extracting measurement results for the sample from the second physical model 414. Additionally, as illustrated with the dotted grey arrow, additional data signals 409 may be used to assist in extracting measurement results for the sample from the second physical model 414. Moreover, the multiple physical models may be optimized independently or co-optimized. For example, in some implementations, as illustrated with dotted grey lines, the first physical model 412 and the second physical model 414 may be linked so that at least some parameters may be coupled across the physical models 412 and 414 and the combined parameter space may be searched to fit the measured signals from one or multiple data sources. The first physical model 412, and optionally, the second physical model 414, may be configured to provide goodness of fit 423 of the physical modeling.

One or more trained machine learning models 422 is used to, based on the multiple data sources, predict parameters of interest 425. A machine learning measurement indicator 427 and goodness of fit 423 from the physical modeling may be reported to indicate the measurement quality of the synergized recipe from physical modeling and machine learning. The trained machine learning model 422, for example, may be the same as the machine learning model 322 of FIG. 3 after it has been trained. As illustrated with the solid black arrow, the trained machine learning model 422 uses the measurement results extracted by the first physical model 412 as input features. As indicated with the dashed black arrows, the trained machine learning model 422 may further use input features including at least one of measured signals 404 from the sample collected from the second source (Source 2), measured signals 406 from the sample collected from the third source (Source 3), additional data signals 409, and the measurement results extracted by the second physical model 414 based on the additional measured signals 404 and/or 406, or any combination thereof. In some implementations, as illustrated with the dotted grey arrow, the trained machine learning model 422 optionally may further use input features including the measured signals 402 from the sample collected from the first source (Source 1). In some implementations, the machine learning input features from the measured signals 402 may include a data channel or a data chunk that are not used in extracting measurement results from the first physical model 412, as discussed in reference to FIG. 3.

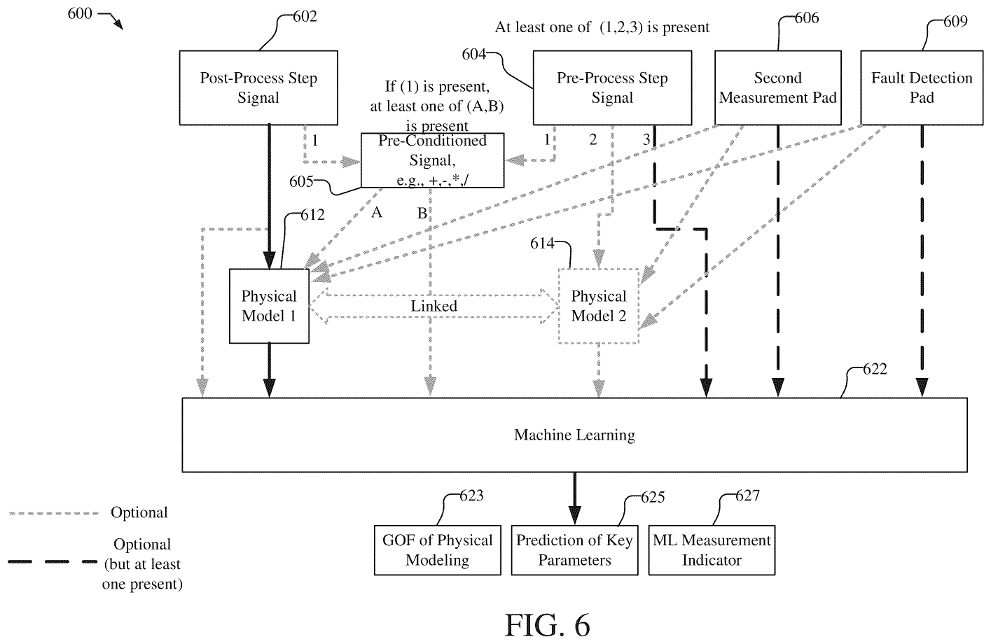

FIG. 5, by way of example, illustrates a workflow 500 for offline recipe creation, e.g., generating one or more physical models and one or more machine learning models, in accordance with a second example scenario with signals collected from multiple data sources, e.g., different manufacturing process steps. In FIG. 5, solid black arrows indicate processes that are used in the workflow 500, dashed black arrows indicate processes that are optional, but at least one is present, while dotted grey arrows indicate processes that are optional.

As illustrated, post-process step measured signals 502 from one or more reference samples are measured from a metrology device. The reference samples, for example, may be OCD target pads or semiconductor devices, and the post-process step measured signals 502 are obtained after a desired step of fabrication of the sample is completed. The post process step measured signals 502 may be collected from any desired metrology device, such as metrology tool 201 shown in FIG. 2, or from any other desired type of metrology device.

Additionally, pre-process step measured signals 504 from the one or more reference samples are measured using the metrology device, e.g., the same metrology device used for acquiring the post-process step measured signals 502, and used to generate pre-process step data. The pre-process step measured signals 504, for example, are obtained prior to a desired step of fabrication of the sample is completed. In some implementations, the post-process step measured signals 502 and pre-process step measured signals 504 may be combined (e.g., combined by addition, subtraction, multiplication, or division) to form pre-conditioned signals 505. Additionally, data 508 related to the reference samples may be collected, such as reference data for the sample, the design of experiment (DOE). In some implementations, the additional data 508 related to the reference samples may further include wafer conditions, precision, tool matching data, etc. Additionally, data may be obtained from other sources, such as from a second measurement pad 506, from a fault detection pad 509, or any combination thereof. While the first example scenario in FIGS. 3 and 4 emphasized multiple data sources collected from different metrology devices, the second example scenario, for example, illustrates that multiple data sources may come from different measurement pads, or same pad at different process steps. The different measurement pads may be measured from the same or different metrology devices. The pre-process step measured signals 504 and the post-process step measured signals 502 may be measured either on designed OCD targets or devices. The second measurement pad 506, for example, refers to pre-process step measurements and/or post-process step measurements from a measurement pad that is not measured for the pre-process step measured signals 504 and the post-process step measured signals 502. If the pre-process step measured signals 504 and the post-process step measured signals 502 are measured on OCD targets, for example, the second measurement pad 506 may refer to signals from device pads, or vice versa.

The signals and data from the multiple data sources may be used to generate one or more physical models. For example, as illustrated with the solid black arrow, the post-process step measured signals 502 from the metrology device may be used to generate a post-process physical model 512 of the sample. In some implementations, additional data may be used to assist in generating the post-process physical model 512. For example, as illustrated with the dotted grey arrow, additional data 508, such as the reference data and/or DOE, and optionally the wafer conditions, precision, and tool matching data, may also be used to assist in the generation of the post-process physical model 512. In another example, as illustrated with the dotted grey arrow, the pre-conditioned signals 505 may be used to assist in the generation of the post-process physical model 512 of the sample. In another example, as illustrated with the dotted grey arrow, signals from the second measurement pad 506 may be used to assist in the generation of the post-process physical model 512 of the sample. In another example, as illustrated with the dotted grey arrow, signals from the fault detection pad 509 may be used to assist in the generation of the post-process physical model 512 of the sample. In some implementations, all or any combination of data 508, and signals from a different measurement pad, e.g., second measurement pad 506 and/or fault detection pad 509 may be used to assist in the generation of the post-process physical model 512.

In some implementations, multiple physical models may be generated. For example, as illustrated with the grey dotted arrows and grey dotted box, a pre-process physical model 514, may be generated based on pre-process step measured signals 504 from the metrology device. In some implementations, additional data may be used to generate the pre-process physical model 514. For example, as illustrated by the dotted grey arrow, additional data 508, such as the reference data and/or DOE, and optionally the wafer conditions, precision, and tool matching data, may also be used to assist in the generation of the pre-process physical model 514. In another example, as illustrated with the dotted grey arrow, signals from the second measurement pad 506 may be used to assist in the generation of the pre-process physical model 514 of the sample. In another example, as illustrated with the dotted grey arrow, signals from the fault detection pad 509 may be used to assist in the generation of the pre-process physical model 514 of the sample. In some implementations, all or any combination of data 508, and signals from the second measurement pad 506 and fault detection pad 509 may be used to assist in the generation of the pre-process physical model 514. Moreover, multiple physical models may be optimized independently or co-optimized. For example, in some implementations, as illustrated with dotted grey lines, the post-process physical model 512 and the pre-process physical model 514 may be linked so that at least some parameters may be coupled across the post-process physical model 512 and the pre-process physical model 514 and the combined parameter space may be searched to fit the measured signals from one or multiple data sources. The post-process physical model 512, and optionally, the pre-process physical model 514, may be configured to provide goodness of fit 523 of the physical modeling.

One or more machine learning models 522 is built and trained using the multiple data sources to predict parameters of interest 525. A machine learning measurement indicator 527 may be developed and reported together with the goodness of fit 523 from the physical modeling to indicate the measurement quality of the recipe synergized from physical modeling and machine learning. As illustrated with the solid black arrows, the machine learning model 522 is built using the post-process measurement results extracted by the post-process physical model 512 as input features. As indicated by the dashed black arrows, the input features of machine learning model 522 additionally includes the pre-process step data that is produced based on the pre-process step measured signals 504. The pre-process step data may be produced based on the pre-process step measured signals 504 in multiple ways. For example, as illustrated in FIG. 5, pre-process step data may be produced in three different ways from the pre-process step measured signals 504, labeled 1, 2, and 3, where at least one of (1), (2), or (3), or any combination thereof, is used. As illustrated with label 1 for the pre-process step measured signals 504, the pre-process step data may be generated by combining the pre-process step measured signals 504 with the post-process step measured signals 502 to form pre-conditioned signals 505. As described in FIG. 5, in some implementations, if the pre-conditioned signals 505 are generated, the pre-conditioned signals 505 may be (A) provided to the post-process physical model 512 and the machine learning model 522 is built based at least in part on the post-process measurement results extracted by the post-process physical model 512, or (B) the pre-conditioned signals 505 are provided to the machine learning model 522 and the machine learning model 522 is built based at least in part on the pre-conditioned signals 505. Additionally, as further described in FIG. 5, in some implementations, at least one of (A) or (B) may be used with workflow 500. As illustrated with label 2 for the pre-process step measured signals 504, the pre-process step data may be generated by providing the pre-process step measured signals 504 to the pre-process physical model 514, and the machine learning model 522 is built based at least in part on the pre-process measurement results extracted by the pre-process physical model 514. As illustrated with label 3 for the pre-process step measured signals 504, the pre-process step data may be generated by providing the pre-process step measured signals 504 to the machine learning model 522, and the machine learning model 522 is built based at least in part on the pre-process step measured signals 504.

Additionally, as indicated with the dashed black arrows, the machine learning model 522 is built using additional data including at least one of pre-process step measured signals 504 (i.e., at least one of (1), (2), or (3) for the pre-process step measured signals 504, or any combination thereof), signals from the second measurement pad 506, and signals from the fault detection pad 509, or any combination thereof. In some implementations, as illustrated with the dotted grey arrows, the machine learning model 522 optionally may be built further using the post-process step measured signals 502, the pre-conditioned signal 505, the measurement results extracted by the pre-process physical model 514, or some combination thereof.

The machine learning model 522 is trained with at least a portion of the data 508, such as the reference data and/or DOE, and optionally the wafer conditions, precision, and tool matching data.

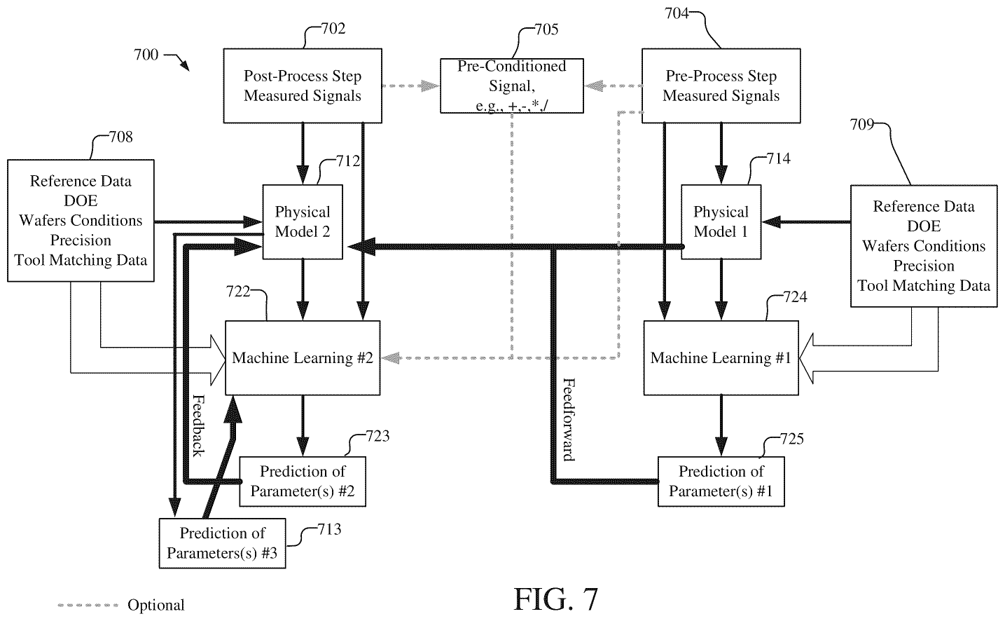

FIG. 6, by way of example, illustrates a workflow 600 for inline measurement, e.g., for characterizing a sample based on one or more physical models and one or more machine learning models, in accordance with the second example scenario with signals collected from multiple data sources, e.g., different manufacturing process steps. The one or more physical models and one or more machine learning models, for example, may be generated as discussed in reference to FIG. 5. In FIG. 6, solid black arrows indicate processes that are used in the workflow 600, dashed black arrows indicate processes that are optional, but at least one is present, while dotted grey arrows indicate processes that are optional.

As illustrated, post-process step measured signals 602 from the sample are collected from a metrology device. The sample, for example, may be an OCD target pad or a semiconductor device, and the post-process step measured signals 602 are obtained after a desired step of fabrication of the sample is completed. The post process step measured signals 602 may be collected from any desired metrology device, such as metrology tool 201 shown in FIG. 2, or from any other desired type of metrology device, and may be collected from the same metrology device or same type of metrology device as used to acquire the post-process step measured signals 502 in FIG. 5.

Additionally, pre-process step measured signals 604 from the sample are collected using the metrology device, e.g., the same metrology device used for acquiring the post-process step measured signals 602, and the same metrology device or same type of metrology device as used to acquire the pre-process step measured signals 504 in FIG. 5. The pre-process step measured signals 604 are used to generate pre-process step data. The pre-process step measured signals 604, for example, are obtained prior to a desired step of fabrication of the sample is completed. In some implementations, the post-process step measured signals 602 and pre-process step measured signals 604 may be combined (e.g., combined by addition, subtraction, multiplication, or division) to form pre-conditioned signals 605. Additionally, data may be obtained from other sources, such as from a second measurement pad 606, from a fault detection pad 609, or any combination thereof. The pre-process step measured signals 604 and the post-process step measured signals 602 may be measured either on designed OCD targets or devices. The second measurement pad 606, for example, refers to pre-process step measurements and/or post-process step measurements from a measurement pad that is not measured for the pre-process step measured signals 604 and the post-process step measured signals 602. If the pre-process step measured signals 604 and the post-process step measured signals 602 are measured on OCD targets, for example, the second measurement pad 606 may refer to auxiliary signals from device pads, or vice versa.

The signals and data from the multiple data sources may be used to extract measurement results from one or more physical models. For example, as illustrated with the solid black arrows, the post-process step measured signals 602 may be used to extract measurement results for the sample from a post-process physical model 612, which may be the same as the post-process physical model 512 in FIG. 5. In some implementations, additional data may be used to assist in extracting measurement results from the post-process physical model 612. For example, as illustrated with the dotted grey arrow, the pre-conditioned signals 605 may be used to assist in the extraction of measurement results from the post-process physical model 612 of the sample. In another example, as illustrated with the dotted grey arrow, signals from the second measurement pad 606 may be used to assist in extracting measurement results from the post-process physical model 612 of the sample. In another example, as illustrated with the dotted grey arrow, signals from the fault detection pad 609 may be used to assist in extracting measurement results from the post-process physical model 612 of the sample. In some implementations, all or any combination of signals from second measurement pad 606 and fault-detection pad 609 may be used to assist in extracting measurement results from the post-process physical model 612.

In some implementations, multiple physical models may be used to extract measurement results for the sample. For example, as illustrated with the black dotted arrows and black dotted box, a pre-process physical model 614 may be used to extract measurement results for the sample based on pre-process step measured signals 604. The pre-process physical model 614 may be the same as the pre-process physical model 614 in FIG. 5. Moreover, multiple physical models may be optimized independently or co-optimized. For example, in some implementations, as illustrated with dotted grey lines, the post-process physical model 612 and the pre-process physical model 614 may be linked so that at least some parameters may be coupled across the post-process physical model 612 and the pre-process physical model 614 and the combined parameter space may be searched to fit the measured signals from one or multiple data sources. The post-process physical model 612, and optionally, the pre-process physical model 614, may be configured to provide goodness of fit 623 of the physical modeling.

One or more trained machine learning models 622 is used, based on the multiple data sources, to predict parameters of interest 625. A machine learning measurement indicator 627 may be developed and reported together with the goodness of fit 623 from the physical modeling to indicate the measurement quality of the recipe synergized from physical modeling and machine learning. As illustrated with the solid black arrows, the trained machine learning model 622 uses the post-process measurement results extracted by the post-process physical model 612 as input data, as well as the pre-process step data that is produced based on the pre-process step measured signals 604.

The pre-process step data may be produced based on the pre-process step measured signals 604 in multiple ways. For example, as illustrated in FIG. 6, pre-process step data may be produced in three different ways from the pre-process step measured signals 604, labeled 1, 2, and 3, where at least one of (1), (2), or (3), or any combination thereof, is used. As illustrated with label 1 for the pre-process step measured signals 604, the pre-process step data may be generated by combining the pre-process step measured signals 604 with the post-process step measured signals 602 to form pre-conditioned signals 605. As described in FIG. 6, in some implementations, if the pre-conditioned signals 605 are generated, the pre-conditioned signals 605 may be (A) provided to the post-process physical model 612 and the trained machine learning model 622 receives input data in the form of post-process measurement results extracted by the post-process physical model 612, or (B) the pre-conditioned signals 605 are provided to the trained machine learning model 622 as input data. Additionally, as further described in FIG. 6, in some implementations, at least one of (A) or (B) may be used with workflow 600. As illustrated with label 2 for the pre-process step measured signals 604, the pre-process step data may be generated by providing the pre-process step measured signals 604 to the pre-process physical model 614, and the trained machine learning model 622 uses the measurement results extracted by the pre-process physical model 614 as input data. As illustrated with label 3 for the pre-process step measured signals 604, the pre-process step data may be generated by providing the pre-process step measured signals 604 to the trained machine learning model 622 as input data.

In some implementations, as illustrated with the dotted grey arrows, the trained machine learning model 622 optionally may further use input data including the post-process step measured signals 602.

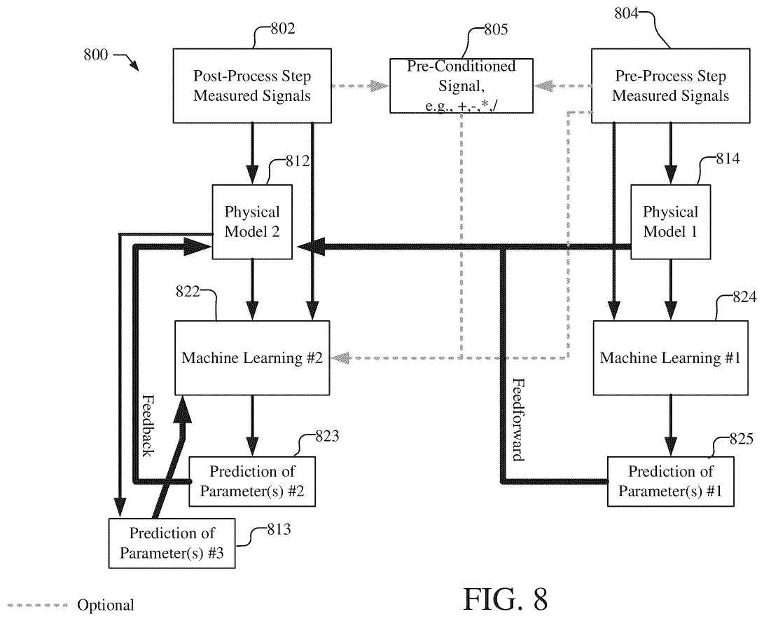

FIG. 7, by way of example, illustrates a workflow 700 for offline recipe creation, e.g., generating one or more physical models and one or more machine learning models, in accordance with a third example scenario with signals collected from multiple data sources, e.g., different manufacturing process steps. The workflow 700, which is based on the third example scenario, for example, may be suitable for measurement of complex 3D structures, including but not limited to GAA transistors, or other devices and provides a method to independently measure different critical dimensions (CD) of a structure of interest, such as the SiGe layer and inner spacer CDs in logic GAA devices, as discussed in FIGS. 1A and 1B, using the hybrid metrology and ecosystem framework discussed herein. In FIG. 7, solid black arrows indicate processes that are used in the workflow 700, while dotted grey arrows indicate processes that are optional.

As illustrated, post-process step measured signals 702 from one or more reference samples are collected from a metrology device. The reference samples, for example, include the SOI, and the post-process step measured signals 702 are obtained after a desired step of fabrication of the sample is completed. The post-process step measured signals 702, may be, e.g., spectral data and may be collected from any desired metrology device, such as metrology tool 201 shown in FIG. 2, or from any other desired type of metrology device.

Additionally, pre-process step measured signals 704 from one or more reference samples are collected using the metrology device, e.g., the same metrology device used for acquiring the post-process step measured signals 702, and used to generate pre-process step data. The pre-process step measured signals 704, for example, are obtained from the reference samples, for example, include the SOI and the pre-process step measured signals 704 are obtained prior to a desired step of fabrication of the sample is completed. The pre-process step measured signals 704, may be, e.g., spectral data and may be collected from same or a different metrology device used to collect the post-process step measured signals 702, which may be any desired metrology device, such as metrology tool 201 or 270 shown in FIG. 2, or from any other desired type of metrology device. In some implementations, the post-process step measured signals 702 and pre-process step measured signals 704 may be combined (e.g., combined by addition, subtraction, multiplication, or division) to form pre-conditioned signals 705.

Additionally, post-process step data 708 related to the SOI of the reference samples at post-process step, e.g., after the desired step of fabrication of the sample is completed, may be collected, such as reference data for the sample and/or the DOE. In some implementations, the additional post-process step data 708 related to the reference samples may further include wafer conditions, precision, tool matching data, etc. Additionally, pre-process step data 709 related to the SOI of the reference samples at pre-process step, e.g., prior to the desired step of fabrication of the sample is completed, may be collected, such as reference data for the sample and/or the DOE. In some implementations, the additional pre-process step data 709 related to the reference samples may further include wafer conditions, precision, tool matching data, etc.

The signals and data from the multiple data sources may be used to generate multiple physical models, such as the pre-process physical model 714 and the post-process physical model 712. For example, as illustrated with the solid black arrow, the pre-process step measured signals 704 from the metrology device may be used to generate a pre-process physical model 714 of the SOI from the sample. In some implementations, additional data may be used to assist in generating the pre-process physical model 714. For example, as illustrated, additional pre-process step data 709, such as the reference data and/or DOE, and optionally the wafer conditions, precision, and tool matching data, may also be used to assist in the generation of the pre-process physical model 714.

Additionally, a pre-process machine learning model 724 is built and trained to predict one or more parameters of interests (parameter(s) #1) 725. As illustrated with the solid black arrows, the pre-process machine learning model 724 is built using the pre-process measurement results extracted by the pre-process physical model 714 as input features. The pre-process machine learning model 724 may be built further using the pre-process step measured signals 704 as input features. The pre-process machine learning model 724 is trained with at least a portion of the pre-process step data 709, such as the reference data and/or DOE, and optionally the wafer conditions, precision, and tool matching data. The one or more parameters of interest (parameter(s) #1) may include a key parameter, i.e., a parameter to be measured at the current process step or a non-key parameter, i.e., a parameter that is not the intended parameter to be measured, or both key and non-key parameters. The parameters of interest (parameter(s) #1) by way of example, may be the Si/SiGe thickness for a GAA transistor, but other parameters of interest, including key parameters or non-key parameters, may be determined for GAA transistors or for other devices being measured.

Additionally, as illustrated with the solid black arrow, the post-process step measured signals 702 from the metrology device may be used to generate a post-process physical model 712 of the SOI from the sample. In some implementations, additional data may be used to assist in generating the post-process physical model 712. For example, as illustrated, additional post-process step data 708, such as the reference data and/or DOE, and optionally the wafer conditions, precision, and tool matching data, may also be used to assist in the generation of the post-process physical model 712. The pre-process step measured signals 704 contain rich information and sensitivity to the one or more parameters of interest (parameter(s) #1) 725, thus accuracy can be improved using such information. Accordingly, as illustrated, the post-process physical model 712 may receive feedforward data from the pre-process physical model 714 and/or from the pre-process machine learning model 724, e.g., for the one or more parameters of interest (parameter(s) #1) 725, to facilitate the propagation of information in the pre-process fabrication step signal to the post-process physical model 712. In some implementations, feedback data produced based on the post-process step measured signals 702 may be used to assist in the generation of the post-process physical model 712. As illustrated, the post-process physical model 712 may receive feedback data for one or more parameters of interest (parameter(s) #2) 723 determined based on the post-process step measured signals 702 by a post-process machine learning model 722 as discussed below. The accuracy of the one or more parameters of interest (parameter(s) #2) 723 benefits from the more accurate one or more parameters of interest (parameter(s) #1) 725 that is fed forward to the post-process physical model 712. Moreover, the feedback of the one or more parameters of interest (parameter(s) #2) 723, may break the high correlation of parameters of interest that experienced the same fabrication step, for example different etched SiGe CDs. For example, the post-process physical model 712 or post-process machine learning model 722 may use the feedback data and may be re-trained with additional post-process step data 708, such as the reference data and/or DOE, and optionally the wafer conditions, precision, and tool matching data, to provide a better prediction on other parameters of interest, e.g., (parameter(s) #3) 713 or (parameter(s) #2) 723.

The post-process machine learning model 722 is built and trained to predict one or more parameters of interests (parameter(s) #2) 723, which may include key parameters, non-key parameters, or both key and non-key parameters. As illustrated with the solid black arrows, the post-process machine learning model 722 is built using the post-process measurement results extracted by the post-process physical model 712 as input features. The post-process machine learning model 722 may be built further using the post-process step measured signals 702 as input features. Additionally, as illustrated by the grey dotted lines, the post-process machine learning model 722 may be built optionally using the pre-conditioned signal 705 and/or the pre-process step measured signal 704 as input features. The post-process machine learning model 722 is trained with at least a portion of the post-process step data 708, such as the reference data and/or DOE, and optionally the wafer conditions, precision, and tool matching data. The parameters, e.g., hyperparameters, weights, biases, etc. of the post-process machine learning model 722 and the post-process physical model 712 may be provided, e.g., reported for characterization of the sample.

As illustrated, the post-process physical model 712 (or separate machine learning models) may be used to predict one or more additional parameters of interests, illustrated as parameters #3 713, which may include key parameters, non-key parameters, or both key and non-key parameters. The post-process parameters of interest, e.g., (parameters #2 and #3) 723, and 713, by way of example, may be the SiGe CD1, SiGe CD2, SiGe CD3, respectively, for a GAA transistor (as illustrated in FIG. 1B), but other parameters of interest may be determined for GAA transistors or for other devices being measured. The workflow 700 illustrated in FIG. 7, for example, may also be applied for other pre and post process steps, for example multiple CD profile measurement in high-aspect ratio (HAR) Channel hole etch, etc. Furthermore, the additional parameters of interests (parameter(s) #3) 713 from the post-process physical model 712 can be further feedforward to the post-process machine learning model 722. The post-process machine learning model 722 can be re-trained with at least a portion of the post-process step data 708, to make the final prediction of additional parameters of interests (parameter(s) #3) 713.

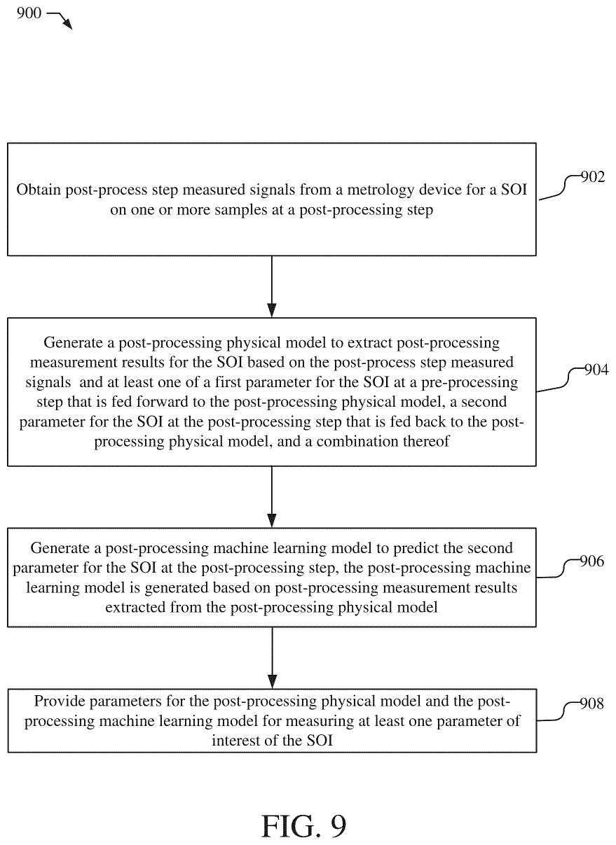

FIG. 8, by way of example, illustrates a workflow 800 for inline measurement, e.g., for characterizing a sample based on one or more physical models and one or more machine learning models, in accordance with the third example scenario with signals collected from multiple data sources, e.g., different manufacturing process steps. The one or more physical models and one or more machine learning models, for example, may be generated as discussed in reference to FIG. 7. In FIG. 8, solid black arrows indicate processes that are used in the workflow 800, while dotted grey arrows indicate processes that are optional.

As illustrated, post-process step measured signals 802 from one or more reference samples are collected from a metrology device. The reference samples, for example, include the SOI, and the post-process step measured signals 802 are obtained after a desired step of fabrication of the sample is completed. The post-process step measured signals 802, may be, e.g., spectral data and may be collected from any desired metrology device, such as metrology tool 201 shown in FIG. 2, or from any other desired type of metrology device, and may be collected from the same metrology device or same type of metrology device as used to acquire the post-process step measured signals 702 in FIG. 7.

Additionally, pre-process step measured signals 804 from the one or more reference samples are collected using the metrology device, e.g., the same metrology device used for acquiring the post-process step measured signals 802, and used to generate pre-process step data. The pre-process step measured signals 804, for example, are obtained from the reference samples, for example, e.g., that include the SOI, and the pre-process step measured signals 804 are obtained prior to a desired step of fabrication of the sample is completed. The pre-process step measured signals 804, may be, e.g., spectral data, and may be collected from the same or a different metrology device used to collect the post-process step measured signals 802, which may be any desired metrology device, such as metrology tool 201 or 270 shown in FIG. 2, or from any other desired type of metrology device and may be the same metrology device or same type of metrology device as used to acquire the pre-process step measured signals 704 in FIG. 7. In some implementations, the post-process step measured signals 802 and pre-process step measured signals 804 may be combined (e.g., combined by addition, subtraction, multiplication, or division) to form pre-conditioned signals 805.

The signals and data from the multiple data sources may be used to extract measurement results from multiple physical models, such as the pre-process physical model 814 and the post-process physical model 812. For example, as illustrated with the solid black arrow, the pre-process step measured signals 804 from the metrology device may be used to extract measurement results from the pre-process physical model 814 of the SOI from the sample.

Additionally, a trained pre-process machine learning model 824 is used to predict one or more parameters of interests (parameter(s) #1) 825. As illustrated with the solid black arrows, the trained pre-process machine learning model 824 uses the pre-process measurement results extracted by the pre-process physical model 814 as input features. The trained pre-process machine learning model 824 may further use the pre-process step measured signals 804 as input features. The one or more parameters of interest (parameter(s) #1), may include key parameters, non-key parameters, or both key and non-key parameters, and by way of example, may be the Si/SiGe thickness for a GAA transistor, but other parameters of interest may be determined for GAA transistors or for other devices being measured.

Additionally, as illustrated with the solid black arrow, the post-process step measured signals 802 from the metrology device may be used to extract measurement results from the post-process physical model 812 of the SOI from the sample. In some implementations, additional data may be used to assist in extracting measurement results from the post-process physical model 812. For example, as illustrated, the post-process physical model 812 may receive feedforward data from the pre-process physical model 814 and/or from the pre-process machine learning model 824, e.g., for the values of one or more parameters of interest (parameter(s) #1) 825, to facilitate the propagation of information in the pre-process fabrication step signal to the post-process physical model 812. In some implementations, feedback data produced based on the post-process step measured signals 802 may be used to assist in extracting measurement results from the post-process physical model 812. As illustrated, the post-process physical model 812 may receive feedback data for, e.g., an initial value of one or more parameters of interest (parameter(s) #2) 823 determined based on the post-process step measured signals 802 by a post-process machine learning model 822 as discussed below. The accuracy of the one or more parameters of interest (parameter(s) #2) 823 benefits from the more accurate one or more parameters of interest (parameter(s) #1) 825 that is fed forward to the post-process physical model 812. Moreover, the feedback of the one or more parameters of interest (parameter(s) #2) 823, may break the high correlation of parameters of interest that experienced the same fabrication step, for example different etched SiGe CDs.

The trained post-process machine learning model 822 is used to predict the final value of one or more parameters of interests (parameter(s) #2) 823 (and one or more initial values of the one or more parameters of interest (parameter(s) #2) 823, if feedback is used), which may include key parameters, non-key parameters, or both key and non-key parameters. As illustrated with the solid black arrows, the trained post-process machine learning model 822 uses the post-process measurement results extracted by the post-process physical model 812 as input features. The trained post-process machine learning model 822 may further use the post-process step measured signals 802 as input features. Additionally, as illustrated by the grey dotted lines, the trained post-process machine learning model 822 may optionally use the pre-conditioned signal 805 and/or the pre-process step measured signals 804 as input features. The final value of the one or more parameters of interest may be provided, e.g., reported, to characterize the sample.

As illustrated, the post-process physical model 812 (or separate machine learning models) may be used to predict one or more additional parameters of interests, illustrated as parameter(s) #3 813, which may include key parameters, non-key parameters, or both key and non-key parameters. The post-process parameters of interest, e.g., (parameters #2 and #3) 823 and 813, by way of example, may be the SiGe CD1, SiGe CD2, SiGe CD3, respectively, for a GAA transistor, but other parameters of interest may be determined for GAA transistors or for other devices being measured. The workflow 800 illustrated in FIG. 8, for example, may also be applied for other pre and post process steps, for example multiple CD profile measurement in high-aspect ratio (HAR) Channel hole etch, etc. Furthermore, the additional parameters of interests (parameter(s) #3) 813 from the post-process physical model 812 can be further feedforward to the post-process machine learning model 822.

In some implementations, the primary data, e.g., the measured signals used in the physical modeling, and the auxiliary data, e.g., the data used only in machine learning, may originate from different tool sets, or may originate from same tool set, but different data channels, or may originate from the same tool set and same data channel but from different wavelength ranges, time spans, etc. Different data sources may collect data from the same sample sites, e.g., OCD target or on device, of the same wafer, from the same process step, or from different process steps. Different data sources may collect data from different sample sites of the same wafer from the same or different process steps, e.g., when underlying structures have correlated parameters, so that analyzing the combined data may improve the overall performance. As illustrated, at least one physical model may be created to analyze measured signals from at least one data source. Moreover, if more than one physical model is used, the multiple physical models may be optimized independently or co-optimized, e.g., the physical models may be linked so that at least some parameters may be coupled across the physical models and the combined parameter space may be searched to fit the measured signals from one or multiple data sources. The main data and the auxiliary data may have different natures, e.g., some of the data may be metrology data collected from a tool set, while other data may be sensor data from process equipment, or wafer process parameters such as gas flow rate, APC parameters, or context data, such a specific process tool. Additionally, feature engineering and signal preprocessing may be applied before data from all sources are provided to the machine learning model for training. The machine learning algorithms, for example, may include, but are not limited to, linear regression, neural networks, deep learning, convolution neural-network (CNN), ensemble methods, support vector machine (SVM), random forest, etc., or combination of multiple models in sequential mode and/or parallel mode.

The illustrated workflows efficiently combine various measurement techniques and the use of multiple data source through synergizing physical modeling and machine learning to produce more usable information than is provided by an individual measurement technique or single data source. The physical modeling may be performed with desired measurement devices using previously well-established modeling solution and the physical modeling results may be combined with other hard or impossible to model data, referred as auxiliary data, for machine learning training and prediction. The resulting process thus provides viable solutions with advantages of both physical modeling and machine learning, while controlling the computation cost, enabling acceptable TTS for production, and is readily implemented and used in practice. Additionally, predictive power may be increased through the use of data, such as process parameters and sensor data from production equipment, which is combined with metrology data through data mining and data fusion as discussed herein. The proposed methods are flexible to accommodate a variety of signals of different nature, while at the same time maximizing usage of existing well-developed algorithms for each type of data source. Moreover, the approach discussed herein has universal application and, for example, may be applied to measurements of any devices, OCD or thin film or other types of targets.

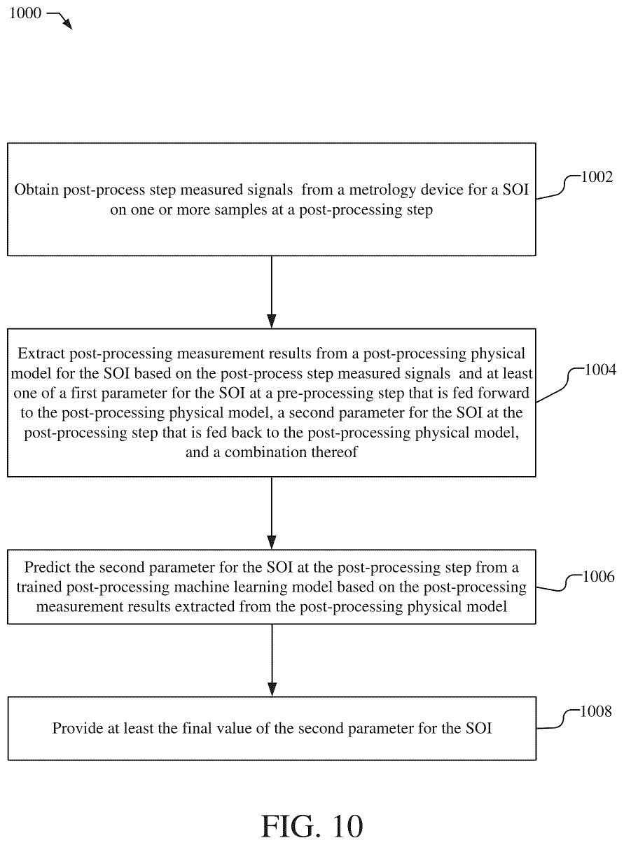

FIG. 9 shows an illustrative flowchart depicting an example method 900 for measuring at least one parameter of interest from a SOI, according to some implementations. In some implementations, the example method 900 may be performed by at least one processor, e.g., such as processor 262 in computing system 260 in FIG. 2, implementing the workflow 700 illustrated in FIG. 7.

The at least one processor may obtain post-process step measured signals from a metrology device for a SOI on one or more samples at a post-process step (902). For example, a means for obtaining post-process step measured signals may be the metrology device 200 and interface with the processor 262 in computing system 260 shown in FIG. 2. The post-process step measured signals for the SOI on one or more samples at a post-process step, for example, may be the post-process step measured signals 702 shown in FIG. 7.

The at least one processor may generate a post-process physical model to extract post-process measurement results for the SOI based on the post-process step measured signals and at least one of a first parameter for the SOI at a pre-process step that is fed forward to the post-process physical model, a second parameter for the SOI at the post-process step that is fed back to the post-process physical model, and a combination thereof (904). The first parameter for the SOI, for example, may be determined by at least one of a pre-process physical model and a pre-process machine learning model for pre-process step measured signals obtained from the SOI on the one or more samples at the pre-process step. For example, the post-process measurement results for the SOI may be extracted based on the post-process step measured signals and the first parameter or the second parameter, or both the first parameter and the second parameter. Moreover, in some implementations, one or more first parameters may be used. In some implementations, one or more second parameters may be used. A means for generating the post-process physical model may be the metrology device 200, including the computing system 260 configured to generate one or more physical models (Model 264pm) by the computer-readable program code 266, shown in FIG. 2. The post-process physical model, for example, may be the post-process physical model 712 that is generated using at least one of a feed forward parameter from the pre-process physical model 714 or the first parameter 725 determined from the pre-process physical model 714 and a pre-process machine learning model 724, or the feedback of the second parameter 723 as illustrated in FIG. 7. In some implementations, each of the first parameter and the second parameter may be a key parameter or a non-key parameter.

The at least one processor may generate a post-process machine learning model to predict the second parameter for the SOI at the post-process step, the post-process machine learning model is generated based on post-process measurement results extracted from the post-process physical model (906). The post-process machine learning model may be further generated based on the post-process step measured signals, and post-process step data including at least one of reference data and design of experiment information for the SOI at the post-process step. For example, a means for generating the post-process machine learning model may be the metrology device 200, including the computing system 260 configured to generate and train one or more machine learning models (ML 264ml) by the computer-readable program code 266, shown in FIG. 2. The post-process machine learning model, for example, may be the post-process machine learning model 722 that is generated based on post-process measurement results extracted from the post-process physical model 712 and the post-process step measured signals 702 and post-process step data 708.

The at least one processor may provide parameters for the post-processing physical model and the post-processing machine learning model for measuring at least one parameter of interest of the SOI (908). For example, a means for providing parameters for the post-processing physical model and the post-processing machine learning model for measuring at least one parameter of interest of the SOI may be the metrology device 200 and interface with the processor 262 and memory 264 in computing system 260 shown in FIG. 2.

In some implementations, the post-process physical model may be generated further based on the post-process step data, e.g., as illustrated by the arrow from post-process step data 708 to the post-process physical model 712 shown in FIG. 7.

In some implementations, the at least one processor may further obtain the pre-process step measured signals from the metrology device for the SOI on the one or more samples at the pre-process step, e.g., as illustrated by pre-process step measured signals 704 shown in FIG. 7. The at least one processor may further generate the pre-process physical model to extract pre-process measurement results for the SOI based on the pre-process step measured signals, e.g., as illustrated by the pre-process physical model 714 shown in FIG. 7. The at least one processor may further generate the pre-process machine learning model to predict the first parameter for the SOI at the pre-process step, e.g., as illustrated by the pre-process machine learning model 724 shown in FIG. 7. The pre-process machine learning model may be generated based on pre-process measurement results extracted from the pre-process physical model and pre-process step data including at least one of reference data and design of experiment information for the SOI at the pre-process step, e.g., as illustrated by the arrows from pre-process physical model 714 to the pre-process machine learning model 724 and from the pre-process step data 709 to the pre-process machine learning model 724 shown in FIG. 7.

In some implementations, the pre-process physical model may be generated further based on the pre-process step data, e.g., as illustrated by the arrow from pre-process step data 709 to the pre-process physical model 714 shown in FIG. 7.

In some implementations, the post-process machine learning model may be generated further based on the pre-process step measured signals from the SOI at the pre-process step, e.g., as illustrated by the arrow from pre-process step measured signals 704 to the post-process machine learning model 722 shown in FIG. 7.

In some implementations, the at least one processor may further generate pre-conditioned signals by combining the pre-process step measured signals from the SOI at the pre-process step and the post-process step measured signals from the SOI at the post-process step, where the post-process machine learning model is generated further based on the pre-conditioned signals, e.g., as illustrated by the pre-conditioned signals 705 and the arrow from pre-conditioned signals 705 to the post-process machine learning model 722 shown in FIG. 7.

In some implementations, the at least one processor may further determine one or more additional parameters for the SOI using at least one of the post-process physical model or the post-process machine learning model, e.g., as illustrated by the prediction of parameter(s) #3 713. In some implementations, the one or more additional parameters may include key parameters, non-key parameters, or a combination of key and non-key parameters.

FIG. 10 shows an illustrative flowchart depicting an example method 1000 for measuring at least one parameter of interest from a SOI, according to some implementations. In some implementations, the example method 1000 may be performed by at least one processor, e.g., such as processor 262 in computing system 260 in FIG. 2, implementing the workflow 800 illustrated in FIG. 8.

The at least one processor may obtain post-process step measured signals from a metrology device for a SOI on one or more samples at a post-process step (1002). For example, a means for obtaining post-process step measured signals may be the metrology device 200 and interface with the processor 262 in computing system 260 shown in FIG. 2. The post-process step measured signals for the SOI on one or more samples at a post-process step, for example, may be the post-process step measured signals 802 shown in FIG. 8.

The at least one processor may extract post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof (1004). For example, the post-process measurement results for the SOI may be extracted based on the post-process step measured signals and the values of the first parameter or the second parameter, or both the first parameter and the second parameter. Moreover, in some implementations, one or more first parameters may be used. In some implementations, one or more second parameters may be used. A means for generating the post-process measurement results extracted from a post-process physical model may be the metrology device 200, including the computing system 260 configured to generate one or more physical models (Model 264pm) by the computer-readable program code 266, shown in FIG. 2. The post-process measurement results may be extracted from a post-process physical model, e.g., as illustrated by the arrow from the post-process physical model 812, based on post-process step measured signals 802 and at least one of a feed forward first parameter 825 determined from the pre-process physical model 814 and a pre-process machine learning model 824 or the feedback of the second parameter 823 as illustrated in FIG. 8. In some implementations, each of the first parameter and the second parameter may be a key parameter or a non-key parameter.

The at least one processor may predict a final value of the second parameter for the SOI at the post-process step from a trained post-process machine learning model based on the post-process measurement results extracted from the post-process physical model (1006). The final value of the second parameter for the SOI may be predicted from the trained post-process machine learning model further based on the post-process step measured signals. For example, a means for predicting a final value of the second parameter for the SOI from a trained post-process machine learning model may be the metrology device 200, including the computing system 260 configured to generate and train one or more machine learning models (ML 264ml) by the computer-readable program code 266, shown in FIG. 2. The final value of the second parameter for the SOI may be predicted by a trained post-process machine learning model, e.g., as illustrated by the parameter(s) #2 823 predicted by the post-process machine learning model 822 based on the post-process measurement results extracted from the post-process physical model and the post-process step measured signals, e.g., as illustrated by the arrow from the post-process physical model 812 to the post-process machine learning model 822 and the post-process step measured signals 802 to the post-process machine learning model 822.

The at least one processor may provide at least the final value of the second parameter for the SOI (1008). For example, a means for providing at least the final value of the second parameter for the SOI may be the metrology device 200 and interface with the processor 262 and memory 264 in computing system 260 and UI 268 shown in FIG. 2.

In some implementations, the value of the first parameter for the SOI, for example, may be determined from at least one of a pre-process physical model and a trained pre-process machine learning model for pre-process step measured signals obtained from the SOI on the one or more samples at the pre-process step. For example, the at least one processor may obtain the pre-process step measured signals from the metrology device for the SOI on the one or more samples at the pre-process step, e.g., as illustrated by pre-process step measured signals 804 shown in FIG. 8. The at least one processor may determine the value of the first parameter from extracted pre-process measurement results for the SOI from the pre-process physical model based on the pre-process step measured signals, e.g., as illustrated by the arrow from the pre-process physical model 814 shown in FIG. 8. In another example, the at least one processor may extract pre-process measurement results for the SOI from the pre-process physical model based on the pre-process step measured signals and predict the value of the first parameter for the SOI at the pre-process step from the trained pre-process machine learning model based on the pre-process measurement results extracted from the pre-process physical model, e.g., as illustrated by the parameter(s) #1 825 predicted by the pre-process machine learning model 824 shown in FIG. 8.

In some implementations, the value of the second parameter for the SOI at the post-process step may be predicted from the trained post-process machine learning model based on initial post-process measurement results extracted from the post-process physical model, e.g., as illustrated by the arrow from post-process physical model 812 to the post-process machine learning model 822 shown in FIG. 8.

In some implementations, the final value of the second parameter for the SOI at the post-process step may be predicted from the trained post-process machine learning model further based on the pre-process step measured signals from the SOI at the pre-process step, e.g., as illustrated by the arrow from pre-process step measured signals 804 to the post-process machine learning model 822 shown in FIG. 8.

In some implementations, the at least one processor may further generate pre-conditioned signals by combining the pre-process step measured signals from the SOI at the pre-process step and the post-process step measured signals from the SOI at the post-process step, where the final value of the second parameter for the SOI at the post-process step is predicted from the trained post-process machine learning model further based on the pre-conditioned signals, e.g., as illustrated by the pre-conditioned signals 805 and the arrow from pre-conditioned signals 805 to the post-process machine learning model 822 shown in FIG. 8.

In some implementations, the at least one processor may further determine one or more additional parameters for the SOI using at least one of the post-process physical model or the post-process machine learning model, e.g., as illustrated by the prediction of parameter(s) #3 813 shown in FIG. 8. In some implementations, the one or more additional parameters may include key parameters, non-key parameters, or a combination of key and non-key parameters.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A method for measuring at least one parameter of interest from a structure of interest (SOI), comprising:
obtaining post-process step measured signals from a metrology device for a SOI on one or more samples at a post-process step;
extracting post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof;
predicting a final value of the second parameter for the SOI at the post-process step from a trained post-process machine learning model based on the post-process measurement results extracted from the post-process physical model; and
providing at least the final value of the second parameter for the SOI.

2. The method of claim 1, wherein the value of the first parameter for the SOI is determined from at least one of a pre-process physical model and a trained pre-process machine learning model based on pre-process step measured signals obtained from the SOI on the one or more samples at the pre-process step.

3. The method of claim 2, further comprising:
obtaining the pre-process step measured signals from the metrology device for the SOI on the one or more samples at the pre-process step; and
determining the value of the first parameter from extracted pre-process measurement results for the SOI from the pre-process physical model based on the pre-process step measured signals.

4. The method of claim 2, further comprising:
obtaining the pre-process step measured signals from the metrology device for the SOI on the one or more samples at the pre-process step;
extracting pre-process measurement results for the SOI from the pre-process physical model based on the pre-process step measured signals; and
predicting the value of the first parameter for the SOI at the pre-process step from the trained pre-process machine learning model based on the pre-process measurement results extracted from the pre-process physical model.

5. The method of claim 1, wherein the value of the second parameter for the SOI at the post-process step is predicted from the trained post-process machine learning model based on initial post-process measurement results extracted from the post-process physical model and the post-process step measured signals.

6. The method of claim 1, wherein the final value of the second parameter for the SOI at the post-process step is predicted from the trained post-process machine learning model further based on a pre-process step measured signals from the SOI at the pre-process step.

7. The method of claim 1, further comprising generating pre-conditioned signals by combining a pre-process step measured signals from the SOI at the pre-process step and the post-process step measured signals from the SOI at the post-process step, wherein the final value of the second parameter for the SOI at the post-process step is predicted from the trained post-process machine learning model further based on the pre-conditioned signals.

8. The method of claim 1, further comprising determining one or more additional parameters for the SOI using at least one of the post-process physical model or the trained post-process machine learning model.

9. A computer system configured for measuring at least one parameter of interest from a structure of interest (SOI) comprising:
at least one processor, wherein the at least one processor is configured to:
obtain post-process step measured signals from a metrology device for a SOI on one or more samples at a post-process step;
extract post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof;
predict a final value of the second parameter for the SOI at the post-process step from a trained post-process machine learning model based on the post-process measurement results extracted from the post-process physical model; and
provide at least the final value of the second parameter for the SOI.

10. The computer system of claim 9, wherein the value of the first parameter for the SOI is determined from at least one of a pre-process physical model and a trained pre-process machine learning model based on a pre-process step measured signals obtained from the SOI on the one or more samples at the pre-process step.

11. The computer system of claim 10, wherein the at least one processor is further configured to:
obtain the pre-process step measured signals from the metrology device for the SOI on the one or more samples at the pre-process step; and
determine the value of the first parameter from an extracted pre-process measurement results for the SOI from the pre-process physical model based on the pre-process step measured signals.

12. The computer system of claim 10, wherein the at least one processor is further configured to:
obtain the pre-process step measured signals from the metrology device for the SOI on the one or more samples at the pre-process step;
extract pre-process measurement results for the SOI from the pre-process physical model based on the pre-process step measured signals; and
predict the value of the first parameter for the SOI at the pre-process step from the trained pre-process machine learning model based on the pre-process measurement results extracted from the pre-process physical model.

13. The computer system of claim 9, wherein the at least one processor is configured to predict the value of the second parameter for the SOI at the post-process step from the trained post-process machine learning model based on initial post-process measurement results extracted from the post-process physical model and the post-process step measured signals.

14. The computer system of claim 9, wherein the at least one processor is configured to predict the final value of the second parameter for the SOI at the post-process step from the trained post-process machine learning model further based on a pre-process step measured signals from the SOI at the pre-process step.

15. The computer system of claim 9, wherein the at least one processor is further configured to generate pre-conditioned signals by combining a pre-process step measured signals from the SOI at the pre-process step and the post-process step measured signals from the SOI at the post-process step, wherein the at least one processor is configured to predict the final value of the second parameter for the SOI at the post-process step from the trained post-process machine learning model further based on the pre-conditioned signals.

16. The computer system of claim 9, wherein the at least one processor is further configured to determine one or more additional parameters for the SOI using at least one of the post-process physical model or the trained post-process machine learning model.

17. A system configured for measuring at least one parameter of interest from a structure of interest (SOI) comprising:
means for obtaining post-process step measured signals from a metrology device for a SOI on one or more samples at a post-process step;
means for extracting post-process measurement results from a post-process physical model for the SOI based on the post-process step measured signals and at least one of a value of a first parameter for the SOI at a pre-process step that is fed forward to the post-process physical model, a value of a second parameter for the SOI at the post-process step that is fed back to the post-process physical model, and a combination thereof;
means for predicting a final value of the second parameter for the SOI at the post-process step from a trained post-process machine learning model based on the post-process measurement results extracted from the post-process physical model; and
means for providing at least the final value of the second parameter for the SOT.

18. The system of claim 17, wherein the value of the first parameter for the SOI is determined from at least one of a pre-process physical model and a trained pre-process machine learning model based on pre-process step measured signals obtained from the SOI on the one or more samples at the pre-process step.

19. The system of claim 17, wherein the value of the second parameter for the SOI at the post-process step is predicted from the trained post-process machine learning model based on initial post-process measurement results extracted from the post-process physical model and the post-process step measured signals.

20. The system of claim 17, wherein the final value of the second parameter for the SOI at the post-process step is predicted from the trained post-process machine learning model further based on a pre-process step measured signals from the SOI at the pre-process step.

21. The system of claim 17, wherein the value of the second parameter for the SOI at the post-process step is predicted from the trained post-process machine learning model based on initial post-process measurement results extracted from the post-process physical model and the post-process step measured signals.

22. The system of claim 17, wherein the final value of the second parameter for the SOI at the post-process step is predicted from the trained post-process machine learning model further based on a pre-process step measured signals from the SOI at the pre-process step.

23. The system of claim 17, further comprising means for generating pre-conditioned signals that combines a pre-process step measured signals from the SOI at the pre-process step and the post-process step measured signals from the SOI at the post-process step, wherein the final value of the second parameter for the SOI at the post-process step is predicted from the trained post-process machine learning model further based on the pre-conditioned signals.

24. The system of claim 17, further comprising means for determining one or more additional parameters for the SOI using at least one of the post-process physical model or the trained post-process machine learning model.
